(19) United States
(12) Patent Application Publication
(10) Pub. No.: US 2026/0122992 A1
(43) Pub. Date: Apr. 30, 2026

(54) SUPPORT STRUCTURE FOR LATERAL GATE MODULE

(71) Applicant: Applied Materials, Inc., Santa Clara, CA (US)

(72) Inventors: Soodoo CHAE, Santa Clara, CA (US); Chando PARK, Palo Alto, CA (US); Mahendra PAKALA, Santa Clara, CA (US)

(21) Appl. No.: 18/927,646

(22) Filed: Oct. 25, 2024

(51) Int. Cl. H01L 29/06; H10B 12/00

(52) U.S. Cl. CPC H10D 62/124; H10B 12/482; H10B 12/485

(57) ABSTRACT

In one embodiments, a memory cell array, includes a first memory stack structure and a support structure. The first memory stack structure includes a first memory structure, a first fin, and a second fin. The first fin extends from a proximal end, coupled to the first memory structure, to a distal end. A first fin side of the first fin couples the proximal ends and the distal ends. The second fin extends from a proximal end, coupled to the first memory structure, to a distal end. A second fin side of the second fin couples the proximal ends and the distal ends. The support structure contacts the first fin side and the second fin side and is spaced from the first memory structure.

### BACKGROUND

### Field

Embodiments described herein generally relate to semiconductor device fabrication, and more particularly, to double-channeled single-gated three-dimensional dynamic random-access memory devices and methods of forming thereof.

### Description of the Related Art

Three-dimensional (3D) dynamic random-access memory (DRAM) devices pose challenges in manufacturability due to their 3D designs and small sizes. As the number of vertical stacks of memory cells in 3D DRAM devices increases (e.g., as chip densities increase), the height of each of the vertical stacks needs to be reduced. Typically, a 3D DRAM device includes individual memory cells, each of which includes a field-effect transistor (FET) having a double gated structure, in which two gates (and word lines connected to the two gates) are disposed on the sides of a silicon channel along the direction of the vertical stacks. However, due to an increased number of layers and fins, fin uniformity can suffer as memory array heights increase with multiple layer.

Therefore there is a need for memory devices with improved fin uniformity and methods for fabrication of such 3D DRAM device structures.

### SUMMARY

In one embodiment, a memory cell array includes a first memory stack structure and a support structure. The first memory stack structure includes a first memory structure, a first fin, and a second fin. The first fin extends from a proximal end, coupled to the first memory structure, to a distal end. A first fin side of the first fin couples the proximal ends and the distal ends. The second fin extends from a proximal end, coupled to the first memory structure, to a distal end. A second fin side of the second fin couples the proximal ends and the distal ends. The support structure contacts the first fin side and the second fin side and is spaced from the first memory structure.

In one embodiment, a memory cell array includes a first memory stack structure, a first bit line, a second memory stack structure and a support structure. The first memory stack structure includes a first memory structure, a first fin, and a second fin. The first fin extends from a proximal end, coupled to the first memory structure, to a distal end. A first fin side of the first fin couples the proximal ends and the distal ends. The second fin is stacked with the first fin and extends from the first memory structure, to a distal end. The first bit line contacts the distal ends of the first fin and the second fin. The second memory stack structure is disposed adjacent to the first memory stack structure. The first memory stack structure and the second memory stack structure are separated by a recess. The second memory stack structure includes a second memory structure, a third fin, and a fourth fin. The third fin extends from a proximal end coupled to the second memory structure to a distal end. The third fin has a third fin side coupling the proximal ends and the distal ends. The fourth fin is stacked with the third fin and extends from the second memory structure to a distal end. The support structure contacts a first support surface of the first fin, a first support surface of the second fin, a first support surface of the third fin, and a first support surface of the fourth fin. The support structure is spaced from the first memory structure and second memory structure and disposed in the recess and between the first fin and third fin and is disposed adjacent the first bit line.

In one embodiment, a method of forming a memory cell array includes performing an oxide etch to form a support recess of a first memory stack structure, disposing a support structure in the support recess, forming a first fin array on a first side of the support structure and a second fin array on a second side of the support structure opposite the first side, and etching a recess between a first memory structure and the support structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic top view of a multi-chamber processing system, according to one or more embodiments of the present disclosure.

FIG. 2A is a schematic view of a portion of a three-dimensional (3D) memory cell array of dynamic random access memory (DRAM) cells according to one embodiment.

FIG. 2B is a schematic diagram of a DRAM cell according to one or more embodiments.

FIG. 3 is a side view of a memory cell array according to one or more embodiments.

FIGS. 4A, 4B, and 4C are an isometric view, a top view, and a side view, respectively, of a memory cell array according to one or more embodiments.

FIGS. 5A, 5B, and 5C are an isometric view, a top view, and a side view, respectively, of a memory cell array according to one or more embodiments.

FIGS. 6A, 6B, and 6C are an isometric view, a top view, and a side view, respectively, of a memory cell array according to one or more embodiments.

FIGS. 7A, 7B, and 7C are an isometric view, a top view, and a side view, respectively, of a memory cell array according to one or more embodiments.

FIGS. 8A, 8B, and 8C are an isometric view, a top view, and a side view, respectively, of a memory cell array according to one or more embodiments.

FIGS. 9A, 9B, and 9C are an isometric view, a top view, and a side view, respectively, of a memory cell array according to one or more embodiments.

FIGS. 10A, 10B, and 10C are an isometric view, a top view, and a side view, respectively, of a memory cell array according to one or more embodiments.

FIGS. 11A, 11B, and 11C are an isometric view, a top view, and a side view, respectively, of a memory cell array according to one or more embodiments.

FIG. 12 is a flow diagram of a method of forming a memory cell array according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide double channeled single gated three-dimensional (3D) dynamic random-access memory (DRAM) devices and methods for forming cell transistors in such 3D DRAM devices. As fin stacks grow in the number of layers, the distal tips of the fins can bend during subsequent operations, reducing uniformity. The support structure described herein enhances uniformity by supporting the sides of the fins during subsequent operations. The support structure described herein also enhances bit line signal speed by shielding adjacent bit lines from each other.

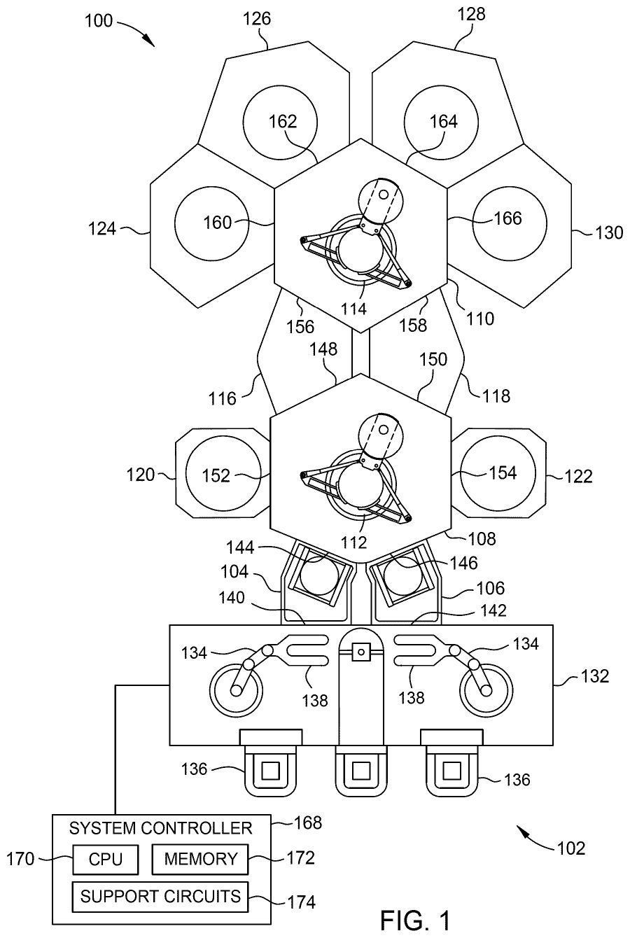

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include integrated processing systems or other suitable processing systems adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes, and the processing chambers 128, 130 can be capable of performing respective epitaxial growth processes.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

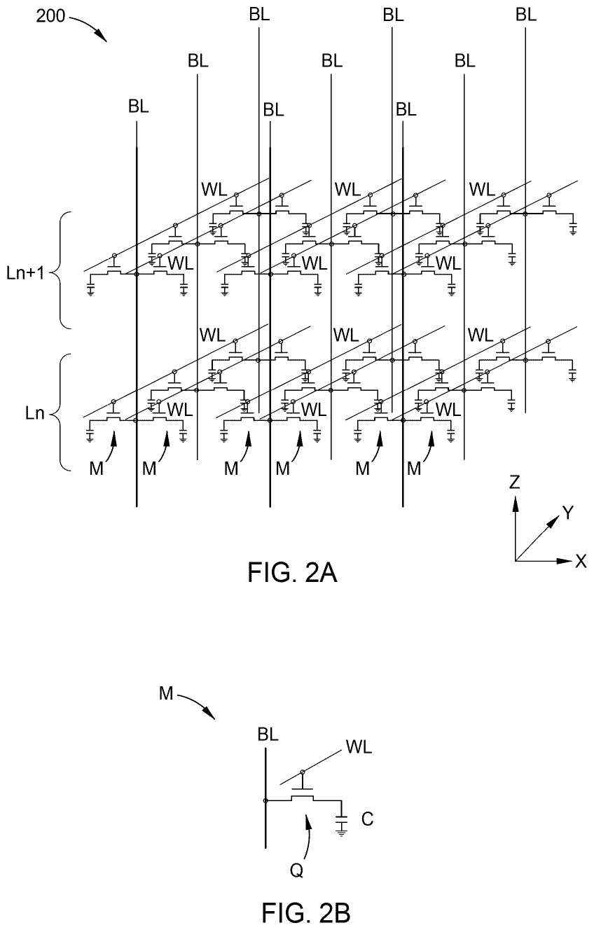

FIG. 2A is a schematic diagram of a portion of a three-dimensional (3D) memory cell array 200 of dynamic random access memory (DRAM) cells (also referred to as “memory cells”) M, according to one or more embodiments of the present disclosure.

As shown in FIG. 2B, a single memory cell M includes an access transistor Q and a storage capacitor C. A memory cell M stores a datum bit by storing a packet of charge (i.e., a binary one) or no charge (i.e., a binary zero) on the storage capacitor C. A datum bit is input and output by a bit line BL that is connected to the source/drain of the access transistor Q, and input is controlled by a word line WL that is connected to the gate of the access transistor Q.

Referring to FIG. 2A, the memory cell array 200 includes memory levels Ln (n=1, 2, . . . ) (a first memory level L, and a second memory level L2 are shown) stacked in the Z direction. Each memory level Ln includes two-dimensional (2-D) array of memory cells M. Although only two memory levels are shown in FIG. 2A, the memory cell array 200 may include more memory levels Ln (n=3, 4, . . . ) stacked above the second memory level L2 in the Z direction.

In the memory cell array 200, bit lines BL extend vertically in the Z direction, and word lines WL extend horizontally in the Y-direction. Each of the bit lines BL is linked to the sources/drains of access transistors Q that are vertically aligned in the Z direction. Each of the word lines WL is linked to the gates of the access transistors that are horizontally aligned in the Y direction.

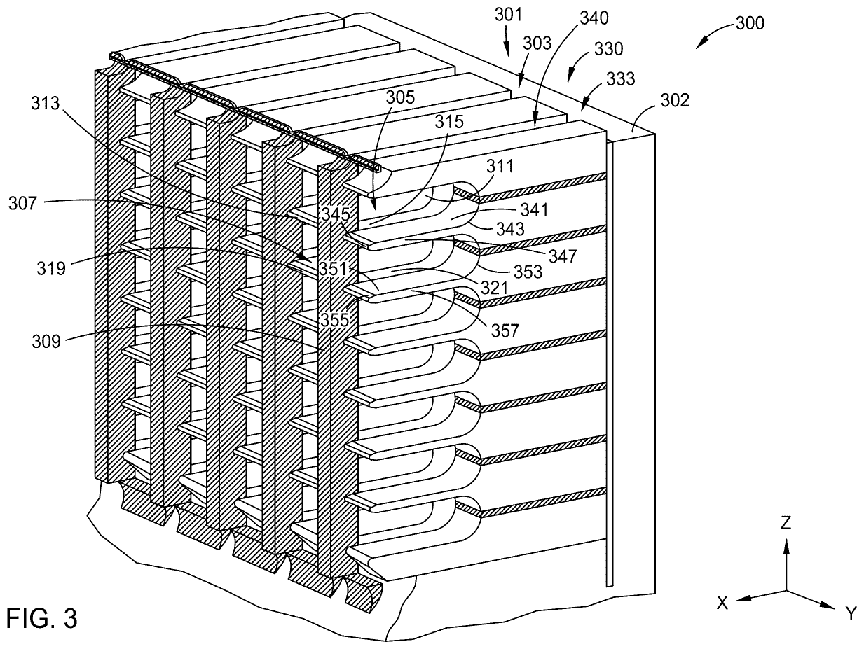

FIG. 3 is a perspective view of a memory cell array 300 according to one or more embodiments.

The memory cell array 300 includes a first memory stack structure 301 coupled to a substrate 302. The first memory stack structure 301 includes a first memory structure 303, a first fin 305, a second fin 307, and a support structure 309. The memory cell array 300 is an array of fins that form the channels and structures for transistors with gate modules disposed there between. For example, each fin is a Si channel layer.

The first fin 305 extends from a proximal end 311 to a distal end 313. The proximal end 311 is coupled to the first memory structure 303. The first fin 305 includes a first fin side 315 coupling the proximal ends 311 and the distal ends 313 of the first fin 305.

The second fin 307 extends from a proximal end 317 to a distal end 319. The proximal end 317 of the second fin is coupled to the first memory structure 303. The second fin 307 is stacked with the first fin 305. The second fin 307 includes a second fin side 321 that couples the proximal end 317 and the distal end 319 of the second fin 307.

The support structure 309 contacts the first fin side 315 of the first fin 305 and the second fin side 321 of the second fin 307. The support structure 309 is spaced from the first memory structure 303. In some embodiments, the support structure 309 extends beyond the distal end 313, 319 of the first fin 305 and the second fin 307.

In some embodiments, the memory cell array 300 includes a second memory stack structure 330. The second memory stack structure 330 is disposed adjacent to the first memory stack structure 301. The first memory stack structure 301 and the second memory stack structure 330 are separated by a recess 340. The support structure 309 is disposed in the recess 340. The second memory stack structure 330 includes a second memory structure 333, a third fin 341, and a fourth fin 351.

The third fin 341 extends from a proximal end 343 to a distal end 345. The proximal end 343 is coupled to the second memory structure 333. The third fin 341 includes a third fin side 347 coupling the proximal end 343 and the distal end 345 of the third fin 341.

The fourth fin 351 extends from a proximal end 353 to a distal end 355. The proximal end 353 is coupled to the second memory structure 333. The fourth fin 351 is stacked with the third fin 341. The fourth fin 351 includes a fourth fin side 357 coupling the proximal ends 353 and the distal ends 355 of the fourth fin 351.

In some embodiments, the support structure 309 extends beyond the distal end 354 of the third fin 341 and the distal end 355 of the fourth fin 351.

The support structure 309 enhances the memory cell array 300 during formation by allowing more stacked layers. By forming the support structure 309 before forming a gate module within the memory cell array 300, the deformation of silicon channels and structures can be reduced, and gate module layers are less likely to cause bending and uniformity issues that reduce ultimate device performance.

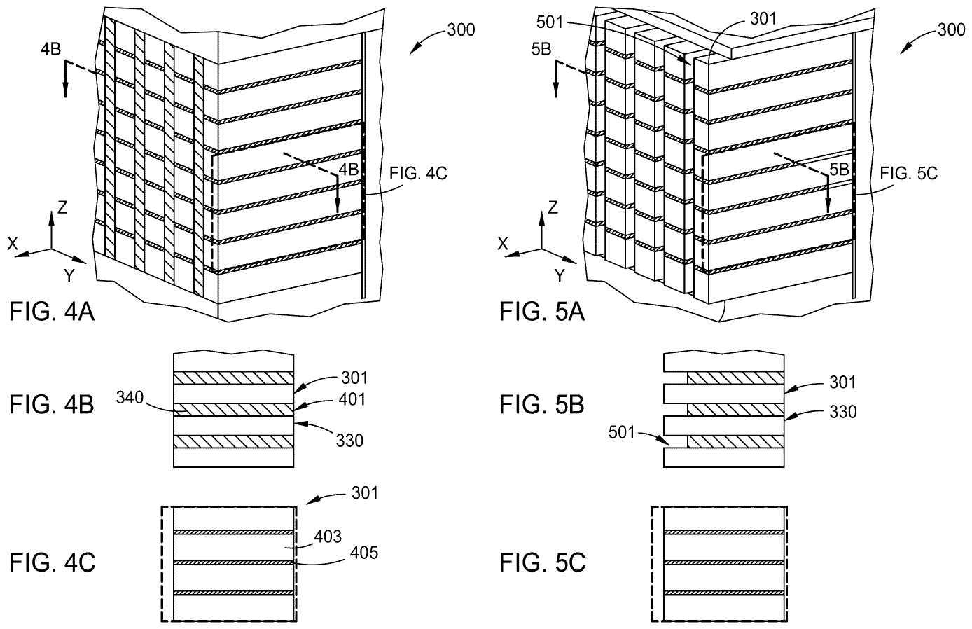

FIGS. 4A, 4B, and 4C through 11A, 11B, and 11C illustrate operations corresponding to the method 1200. For clarity, the operations of method 1200 will be discussed in association with the corresponding figures in FIGS. 4A, 4B, and 4C through 11A, 11B, and 11C.

FIGS. 4A, 4B, and 4C are an isometric view, a top view, and a side view, respectively, of the memory cell array 300 according to one or more embodiments.

The memory cell array 300 includes the first memory stack structure 301 and the second memory stack structure 330. FIG. 4B illustrates a cross section cut in the X-Y plane. As illustrated in FIG. 4B the first memory stack structure 301 and the second memory stack structure 330 are separated by a dielectric material 401 disposed in the recess 340. In some embodiments, the dielectric material 401 is an oxide. The dielectric material 401 is silicon oxide (SiO₂) according to some embodiments.

FIG. 4C illustrates a cross section cut in the X-Z plane. As illustrated in FIG. 4C, the first memory stack structure 301 includes a plurality of stacked layers. The plurality of stacked layers alternate in the Z direction and include a first layer 403 and a second layer 405. In some embodiments, the first layer 403 is a silicon layer, and the second layer 405 includes germanium, for example a silicon-germanium (SiGe) layer. In some embodiments, either one of or both of the first layer 403 and the second layer 405 can be doped. For example, the first layer 403 is a doped silicon layer. In another example, the second layer 405 is a doped SiGe layer. Dopants of the first and/or second layer include one or more of boron, phosphorus, and arsenic, or any combination thereof, but other dopants are contemplated.

FIGS. 5A, 5B, and 5C are an isometric view, a top view, and a side view, respectively, of the memory cell array 300 according to one or more embodiments.

At operation 1201 as seen in FIGS. 5A, 5B, and 5C, the processing system 100 (FIG. 1) performs an etch operation to form a support recess 501 of the first memory stack structure 301. The etch operation may be an oxide etch that removes a portion of the dielectric material 401 to form the support recess 501. In some embodiments, the support recess 501 is formed as a vertical etch between the first memory stack structure 301 and the second memory stack structure 330.

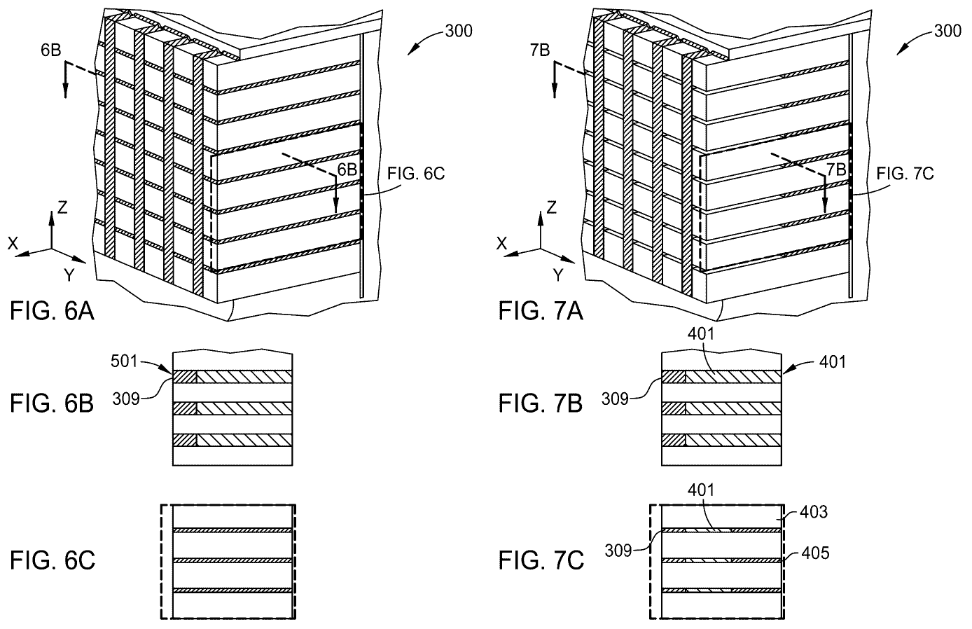

FIGS. 6A, 6B, and 6C are an isometric view, a top view, and a side view, respectively, of the memory cell array 300 according to one or more embodiments.

At operation 1203 as seen in FIGS. 6A, 6B, and 6C, the processing system 100 (FIG. 1) disposes the support structure 309 in the support recess 501. The support structure 309 may be a silicone containing material, a low k dielectric material, a metal oxide, a metal nitride, a metal, include carbon, or any combination thereof. For example, the support structure 309 may include silicon, oxygen, carbon, and nitrogen. Examples of silicon containing materials for the support structure 309 include SiOCN, SiCN, SiBN, SiON, SiOC, SiN. Examples of metal oxides include AIO and ZrO. Examples of metal nitrides include AlN and TIN. Examples of the metal include rubidium and tungsten. Examples of carbon based materials include carbon (C), SiC, BC, and SiBC.

FIGS. 7A, 7B, and 7C are an isometric view, a top view, and a side view, respectively, of the memory cell array 300 according to one or more embodiments.

In some embodiment, the method 1200 includes a horizontal etch operation. The horizontal etch removes portions of the second layers 405 from between the first layers 403. As illustrated in FIG. 7C, the horizontal etch exposes side surfaces of the support structure 309 and the dielectric material 401. The horizontal etch is a selective removal operation. A selective removal operation is a material specific and direction specific operation. For example, the horizontal etch is a silicon germanium etch about parallel to the X-Y plane.

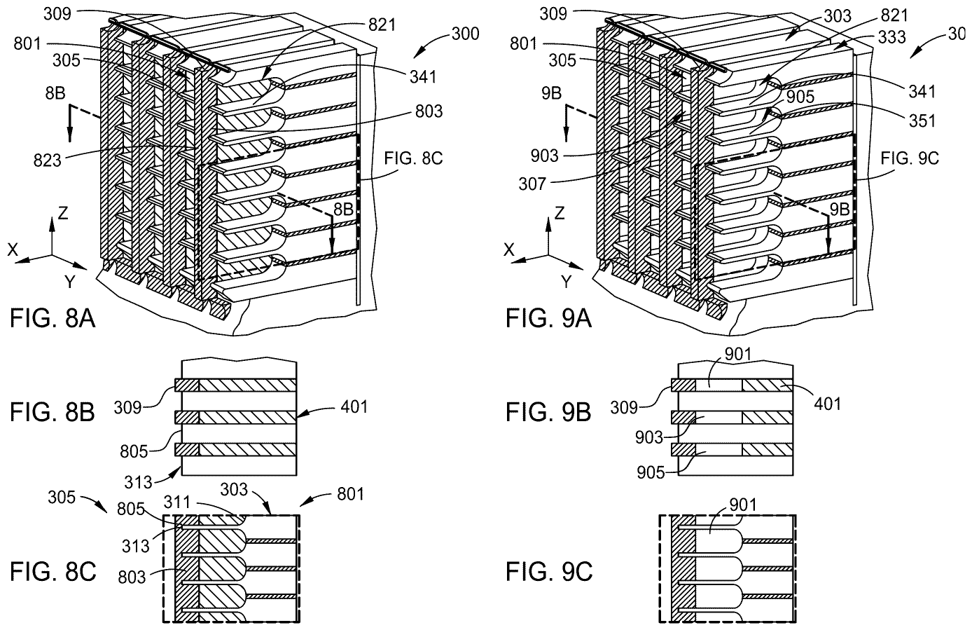

FIGS. 8A, 8B, and 8C are an isometric view, a top view, and a side view, respectively, of the memory cell array 300 according to one or more embodiments.

At operation 1205, as seen in FIGS. 8A, 8B, and 8C, the processing system 100 (FIG. 1) forms a first fin array 801 on a first side 803 of the support structure 309 and a second fin array 821 on a second side 823 of the support structure 309 opposite the first side 803. In some embodiments, operation 1205 is a wet etch operation. The first fin array 801 includes the first fin 305 and the second fin array 821 includes the third fin 341. The first fin 305 is disposed about parallel to the third fin 341.

Once formed, the first fin array 801 includes the first fin 305. As illustrated in FIG. 8C, the first fin 305 includes a ridge 805 disposed on the distal end 313 of the first fin 305. The ridge 805 is disposed perpendicular to the support structure 309. For example, the ridge 805 is disposed perpendicular to the first side 803 of the support structure 309 and perpendicular to the first fin side 315 and the fourth fin side 357 (FIG. 3) to form a lateral fin edge of the first fin array 801.

As further illustrated in FIG. 8C, the proximal end 311 is coupled to the first memory structure 303 and the distal end 313 is coupled to the support structure 309.

FIGS. 9A, 9B, and 9C are an isometric view, a top view, and a side view, respectively, of the memory cell array 300 according to one or more embodiments.

At operation 1207, as seen in FIGS. 9A, 9B, and 9C, the processing system 100 (FIG. 1) performs an etching operation to form a recess 901 between the first memory structure 303 and the support structure 309. The etching operation 1207 etches away a portion of the dielectric material 401, to form the recess 901. The etching operation 1207 may be a wet etch using HF or a gas based etch, but other types of etching operations are contemplated.

In some embodiments, the etching operation 1207 is a vertical etch operation that occurs after forming the first fin array 801 and the second fin array 821 to form the recess 901 by etching away the dielectric material 401 between the support structure 309 and the proximal ends 311, 317, 343, 353 of the fins 305, 307, 341, 351.

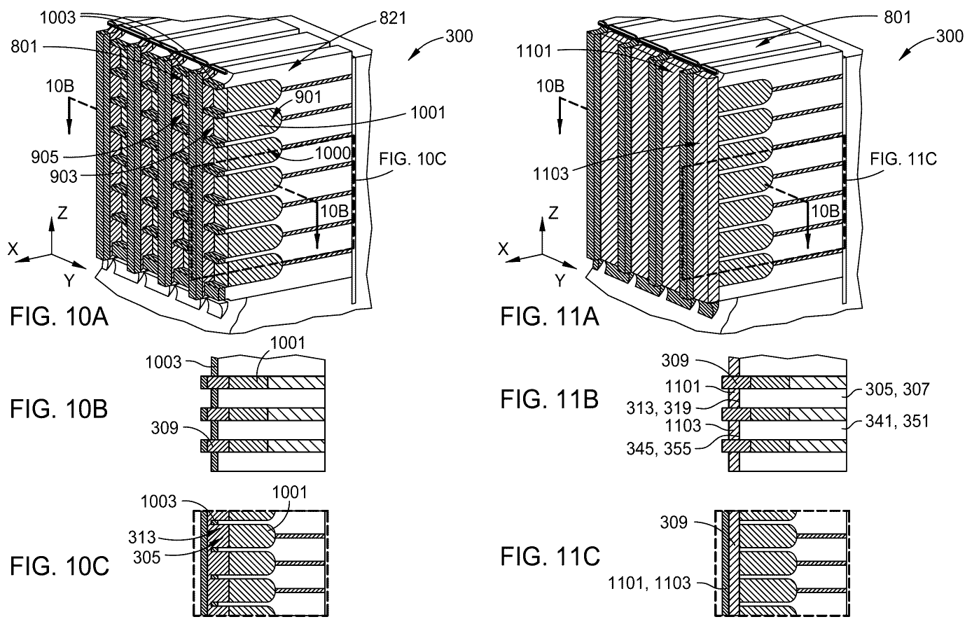

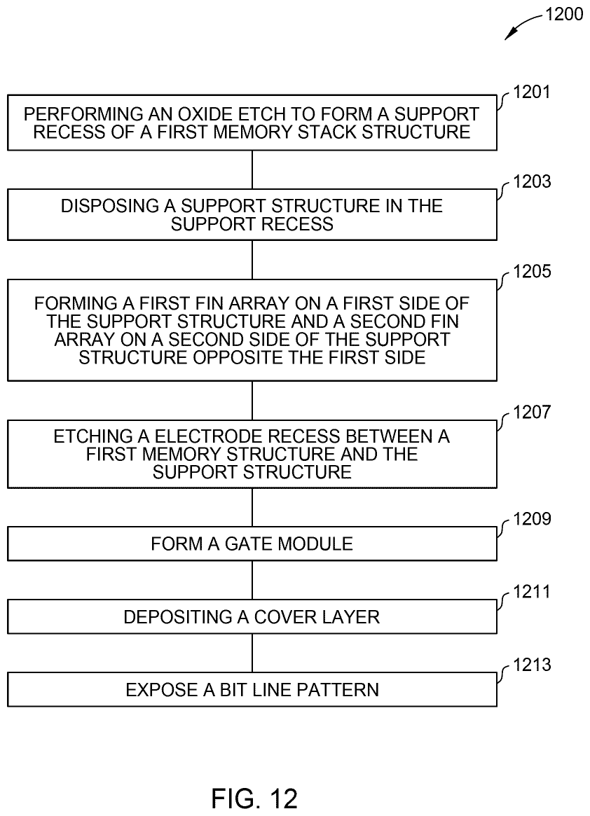

In some embodiments, forming the recess 901 includes forming a first gate region 903 partially defined by the first fin 305 and the second fin 307 and forming a second gate region 905 partially defined by the third fin 341 and fourth fin 351. After the etching operation 1207, a plurality of gate modules 1000 (FIGS. 10A, 10B, and 10C) are formed. The first fin 305 and the third fin 341 are part of a first row of fins and the second fin 307 and the fourth fin 351 are part of a second row of fins. The plurality of gate modules 1000 include gate lines disposed between the first row of fins and the second row of fins. By etching away the dielectric material 401 to form gate regions on the lateral sides of the fins, laterally adjacent gate modules are able to form a gate line that passes laterally through gate regions and parallel to the rows of fins.

FIGS. 10A, 10B, and 10C are an isometric view, a top view, and a side view, respectively, of the memory cell array 300 according to one or more embodiments.

At operation 1209, as seen in FIGS. 10A, 10B, and 10C, the processing system 100 (FIG. 1) forms the plurality of gate modules 1000. Forming the gate modules 1000 includes forming a plurality of gate electrodes 1001 and depositing gate module material 1003 over the support structure 309 and distal end 313 of the first fin 305. In some embodiments, depositing gate module material 1003 over the support structure 309 and distal end 313 of the first fin 305 includes depositing a nitride or an oxide on the support structure 309 and distal end 313 of the first fin 305. In some embodiments, the first gate region 903 is coupled to the second gate region 905 by a gate electrode 1001. The gate electrode 1001 is disposed in the recess 901.

In some embodiments, forming a plurality of gate modules 1000 further includes forming a plurality of gate modules 1000 within the first fin array 801 and a plurality of gate modules 1000 within the second fin array 821.

At operation 1211, the processing system 100 (FIG. 1) deposits a bit line cover layer over the memory cell array 300. In some embodiments, the bit line cover layer is deposited over the entire memory cell array 300. In some embodiments, the bit line cover layer is selectively deposited over vertical sections of the memory cell array 300, for example, over the bit line cover layer is selectively deposited over the stack structures 301 330. For example, depositing a bit line cover layer over the first memory stack structure 301. In some embodiments, the bit line cover layer is titanium nitride (TIN), but other materials are contemplated.

FIGS. 11A, 11B, and 11C are an isometric view, a top view, and a side view, respectively, of the memory cell array 300 according to one or more embodiments.

At operation 1213, as seen in FIGS. 11A, 11B, and 11C the processing system 100 (FIG. 1) forms one or more bit lines. For example, operation 1213 forms a first bit line 1101 and second bit line 1103 by exposing the bit line coating to an etch operation. In some embodiments, the etch operation is a vertical etch that leaves the bit line 1101 disposed over the first fin array 801 and about parallel to the support structure 309.

In some embodiments, the first bit line 1101 contacts the distal end 313 of the first fin 305 and the distal end 319 of the second fin 307 and the second bit line 1103 contacts the distal end 345 of the third fin 341 and the distal end 355 of the fourth fin 351.

The support structure 309 shields the first bit line 1101 from the second bit line 1103 and the support structure 309 is disposed between the first bit line 1101 and the second bit line 1103. By shielding the bit lines, the support structure 309 reduces the effect of RC delay on the bit lines. When a signal propagates through the bit line, the signal experiences a delay due to the combination of resistance and capacitance of the bit line. This delay is characterized by the RC time constant, the RC delay. The support structure 309 shields adjacent bit lines from each other to allow for faster signal speed for random access memory applications.

Benefits of the present disclosure include at least reduced deformation of the memory cell array 300 during production steps, enhanced bit line shielding for reduced RC delay, and greater number of stacked layers.

It is contemplated that one or more aspects disclosed herein may be combined. As an example, one or more aspects, features, components, operations and/or properties of the memory cell array 300 and method 1200 may be combined.

While the foregoing is directed to embodiments of the present disclosure, other and further embodiments of the disclosure may be devised without departing from the basic scope thereof, and the scope thereof is determined by the claims that follow.

What is claimed:

1. A memory cell array, comprising:
a first memory stack structure comprising:
a first memory structure;
a first fin extending from a proximal end to a distal end, the proximal end coupled to the first memory structure, the first fin having a first fin side coupling the proximal ends and the distal ends of the first fin; and
a second fin extending from a proximal end to a distal end, the proximal end of the second fin coupled to the first memory structure, the second fin stacked with the first fin, the second fin having a second fin side coupling the proximal ends and the distal ends of the second fin; and
a support structure contacting the first fin side of the first fin and the second fin side of the second fin, the support structure spaced from the first memory structure.

2. The memory cell array of claim 1, wherein the support structure extends beyond the distal end of the first fin and the second fin.

3. The memory cell array of claim 1, wherein a first bit line contacts the distal end of the first fin and the second fin.

4. The memory cell array of claim 3, further comprising:
a second memory stack structure disposed adjacent to the first memory stack structure, the first memory stack structure and the second memory stack structure separated by a recess, the support structure disposed in the recess, the second memory stack structure comprising:
a second memory structure;
a third fin extending from a proximal end to a distal end, the proximal end coupled to the second memory structure, the third fin having a third fin side coupling the proximal ends and the distal ends of the third fin; and
a fourth fin extending from a proximal end to a distal end, the proximal end of the fourth fin coupled to the second memory structure, the fourth fin stacked with the third fin, the fourth fin having a fourth fin side coupling the proximal ends and the distal ends of the fourth fin.

5. The memory cell array of claim 4, wherein the support structure extends beyond the distal end of the third fin and the distal end of the fourth fin.

6. The memory cell array of claim 4, wherein a second bit line contacts the distal end of the third fin and the distal end of the fourth fin.

7. The memory cell array of claim 6, wherein the support structure shields the first bit line from the second bit line.

8. A memory cell array, comprising:
a first memory stack structure comprising:
a first memory structure;
a first fin extending from a proximal end to a distal end, the proximal end coupled to the first memory structure, the first fin having a first fin side coupling the proximal ends and the distal ends of the first fin; and
a second fin extending to a distal end, the second fin coupled to the first memory structure, the second fin stacked with the first fin,;
a first bit line contacting the distal ends of the of the first fin and the second fin;
a second memory stack structure disposed adjacent to the first memory stack structure, the first memory stack structure and the second memory stack structure separated by a recess, the second memory stack structure comprising:
a second memory structure;
a third fin extending from a proximal end to a distal end, the proximal end coupled to the second memory structure, the third fin having a third fin side coupling the proximal ends and the distal ends of the third fin; and
a fourth fin extending to a distal end, the fourth fin coupled to the second memory structure, the fourth fin stacked with the third fin; and
a support structure contacting the first fin, the second fin, the third fin, and the fourth fin, the support structure spaced from the first memory structure and second memory structure, the support structure disposed in the recess and between the first fin and third fin and is disposed adjacent the first bit line.

9. The memory cell array of claim 8, wherein a second bit line contacts the distal end of the third fin and the distal end of the fourth fin.

10. The memory cell array of claim 9, wherein the support structure is disposed between the first bit line and the second bit line.

11. The memory cell array of claim 8, wherein the first fin further comprises a ridge disposed on the distal end, the ridge disposed perpendicular to the support structure and perpendicular to the first fin side and a fourth fin side.

12. The memory cell array of claim 8, further comprising:
a first gate region partially defined by the first fin and the second fin; and
a second gate region partially defined by the third fin and the fourth fin.

13. The memory cell array of claim 12, wherein the first gate region is coupled to the second gate region by a gate electrode, the gate electrode disposed in the recess.

14. The memory cell array of claim 8, wherein the first fin is disposed about parallel to the third fin.

15. A method of forming a memory cell array, the method comprising:
performing an etch to form a support recess of a first memory stack structure;
forming a support structure in the support recess;
forming a first fin array on a first side of the support structure and a second fin array on a second side of the support structure opposite the first side; and
etching a recess between a first memory structure and the support structure.

16. The method of claim 15, further comprising:
forming a first bit line over the first fin array; and
forming a second bit line over the second fin array, the support structure disposed between the first bit line and the second bit line.

17. The method of claim 15, wherein etching a recess between a first memory structure and the support structure comprises:
performing a vertical etch after forming the first fin array and the second fin array to form the recess.

18. The method of claim 15, wherein forming the first fin array further comprises forming a first fin of the first fin array, the first fin comprising:
a proximal end coupled to the first memory structure; and
a distal end coupled to the support structure.

19. The method of claim 15, further comprising:
forming a plurality of gate modules within the first fin array and a plurality of gate modules within the second fin array;
depositing a bit line coating over the first memory stack structure; and
forming a bit line by exposing the bit line coating, the bit line disposed over the first fin array and about parallel to the support structure.

20. The method of claim 19, wherein forming a plurality of gate modules further comprises:
forming a plurality of gate electrodes in the recess, the gate electrode coupling the gate modules of the first fin array and the gate modules of the second fin array.
